(19) United States
(12) Patent Application Publication
(10) Pub. No.: US 2008/0029019 A1
(43) Pub. Date: Feb. 7, 2008

(54) Method For Producing Directionally Solidified Silicon Ingots

(75) Inventors: Christian Dethloff, Oslo (NO); Kenneth Friestad, Kristiansand (NO)

Correspondence Address: LUCAS & MERCANTI, LLP, 475 PARK AVENUE SOUTH, 15TH FLOOR, NEW YORK, NY, 10016, US

(73) Assignee: ELKEM SOLAR AS, Oslo (NO)

(21) Appl. No.: 11/722,813

(22) PCT Filed: Nov. 17, 2005
(86) PCT No.: PCT/NO05/00432

§ 371 Date: Jun. 26, 2007

(30) Foreign Application Priority Data
Dec. 27, 2004 (NO) 20045665

(51) Int. Cl. C30B 15/00; C30B 15/04; C30B 29/06

(52) U.S. Cl. 117/13; 117/21

(57) ABSTRACT

The present invention relates to a method for the production of directionally solidified Czochralski, float zone or multicrystalline silicon ingots or thin sheets or ribbon for making wafers for solar cells from silicon feedstock initially containing between 0.2 ppma and 10 ppma boron and between 0.1 ppma and 10 ppma phosphorous. If the boron content in the silicon feedstock is higher than the phosphorous content, the boron content in the molten silicon is kept higher than the phosphorous content during the directional solidification process by adding boron to the molten silicon in order to extend the part of the directionally solidified ingot or the thin sheet or ribbon solidifying as p-type material. If the content of phosphorous in the silicon feedstock is higher than the boron content, the phosphorous content in the molten silicon is kept higher than the boron content during the directional solidification process by adding phosphorous to the molten silicon in order to extend the part of the ingot or the thin sheet or ribbon solidifying as n-type material.

### TECHNICAL FIELD

The present invention relates to a method for the production of directionally solidified Czochralski, float zone or multicrystalline silicon ingots, thin silicon sheets or ribbons for the production of silicon wafers for photovoltaic (PV) solar cells.

### BACKGROUND TECHNOLOGY

In recent years, photovoltaic solar cells have been produced from ultra pure virgin electronic grade polysilicon (EG-Si) supplemented by suitable scraps, cuttings and rejects from the electronic chip industry. As a result of the recent downturn experienced by the electronics industry, idle polysilicon production capacity has been adapted to make available lower cost grades suitable for manufacturing PV solar cells. This has brought a temporary relief to an otherwise strained market for solar grade silicon feedstock (SoG-Si) qualities. With demand for electronic devices returning to normal levels, a major share of the polysilicon production capacity is expected to be allocated back to supply the electronics industry, leaving the PV industry short of supply. The lack of a dedicated, low cost source of SoG-Si and the resulting supply gap developing is today considered one of the most serious barriers to further growth of the PV industry.

In recent years, several attempts have been made to develop new sources for SoG-Si that are independent of the electronics industry value chain. Efforts encompass the introduction of new technology to the current polysilicon process routes to significantly reduce cost as well as the development of metallurgical refining processes purifying abundantly available metallurgical grade silicon (MG—Si) to the necessary degree of purity. None have so far succeeded in significantly reducing cost of production while providing a silicon feedstock purity expected to be required to match the performance of PV solar cells produced from conventional silicon feedstock qualities today.

When producing PV solar cells, a charge of SoG-Si feedstock is prepared, melted and directionally solidified into a square ingot in a specialized casting furnace. Before melting, the charge containing SoG-Si feedstock is doped with either boron or phosphorus to produce p-type or n-type ingots respectively. With few exceptions, commercial solar cells produced today are based on p-type silicon ingot material. The addition of the single dopant (eg. boron or phosphorus) is controlled to obtain a preferred electrical resistivity in the material, for example in the range between 0.5-1.5 ohm cm. This corresponds to an addition of 0.02-0.2 ppma of boron when a p-type ingot is desired and an intrinsic quality (practically pure silicon with negligible content of dopants) SoG-Si feedstock is used. The doping procedure assumes that the content of the other dopant (in this example case phosphorus) is negligible (P< 1/10 B).

In Norwegian patent application No. 20035830 filed Dec. 29, 2003 it is disclosed a method for producing directionally solidified Czochralski, float zone or multicrystalline silicon ingots or thin silicon sheets or ribbon for making wafers based on a silicon feedstock material produced from metallurgical grade silicon by means of metallurgical refining processes. The silicon feedstock contains between 0.2 ppma and 10 ppma boron and between 0.1 and 10 ppma phosphorous. Due to the content of boron and phosphorous the silicon ingot produced according to Norwegian patent application No. 20035830 will have a characteristic type change from p-type to n-type at a position between 40 and 99% of the ingot height or sheet or ribbon thickness, depending on the ratio between boron and phosphorous in the silicon feedstock. Thus the ingots produced will contain both p-type and n-type silicon.

It is desirable to produce only p-type or only n-type material from the silicon feedstock containing both boron and phosphorous, but in the examples in Norwegian patent application No. 20035830 the change from p-type to n-type takes place at about ¾ of the height of the ingot.

### DESCRIPTION OF INVENTION

It is an object of the present invention to provide a method for increasing the amount of either p-type or n-type material in a directionally solidified silicon ingot or thin sheet or ribbon produced from a silicon feedstock containing both boron and phosphorous.

The present invention thus relates to a method for the production of directionally solidified Czochralski, float zone or multicrystalline silicon ingots or thin sheets or ribbon for making wafers for solar cells from silicon feedstock initially containing between 0.2 ppma and 10 ppma boron and between 0.1 ppma and 10 ppma phosphorous which method is characterized in that if the boron content in the silicon feedstock is higher than the phosphorous content, the boron content in the molten silicon is kept higher than the phosphorous content during the directional solidification process by adding boron discontinuously, continuously or substantially continuously to the molten silicon in order to extend the part of the directionally solidified ingot or the thin sheet or ribbon solidifying as p-type material with a preset resistivity or within a preset resistivity range, or if the content of phosphorous in the silicon feedstock is higher than the boron content, the phosphorous content in the molten silicon is kept higher than the boron content during the directional solidification process by adding phosphorous to the molten silicon discontinuously, continuously or substantially continuously in order to extend the part of the ingot or the thin sheet or ribbon solidifying as n-type material with a preset resistivity or within a given resistivity range.

By the method of the present invention it has been found that the part of the directionally solidified ingot or thin sheet or ribbon can be substantially extended before the change from p-type material to n-type material or from n-type material to p-type material.

### SHORT DESCRIPTION OF THE DRAWINGS

FIG. 1 is a diagram showing the resistivity for a directionally solidified silicon ingot made according to the prior art, and

FIG. 2 is a diagram for the resistivity for a directionally solidified ingot made according to the method of the present invention.

### DETAILED DESCRIPTION OF THE INVENTION

### EXAMPLE 1 (PRIOR ART)

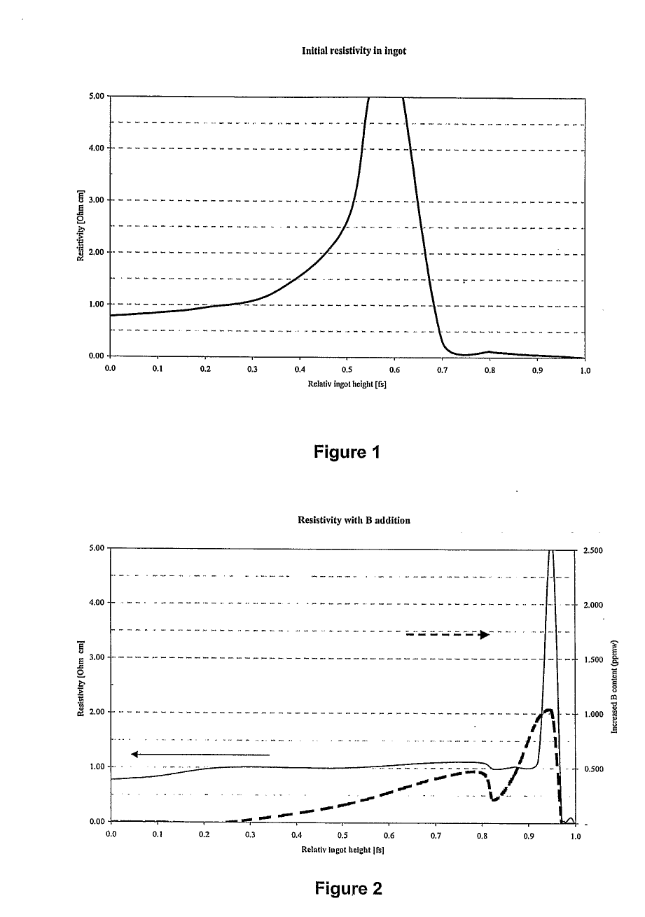

A directionally solidified silicon ingot was produced from a silicon feedstock initially containing 0.8 ppma boron and 3.6 ppma phosphorous. The change from p-type material to n-type material in this silicon ingot took place at about 60% height of the solidified ingot. The resistivity in the produced silicon ingot is shown in FIG. 1 and it can be seen from the figure that the change from p-type material to n-type material took place at about 60% of the height of the ingot.

### EXAMPLE 2 (INVENTION)

A directionally solidified silicon ingot was produced from the same silicon is feedstock as used in Example 1. Boron was continuously added to the remaining molten silicon when about 50% of the ingot had been solidified. The change from p-type material to n-type material took place at more than 90% of the height of the solidified ingot As can be seen from FIG. 2. The amount of boron added to the silicon melt is also shown in FIG. 2.

By comparing the results of Examples 1 and 2 it can be seen that the change form p-type material to n-type material was moved from about 60% of the height of the silicon ingot to more than 90% of the height of the silicon ingot.

Thus, by the present invention it is possible to substantially increase the part of a directionally solidified ingot solidifying either as p-type material or n-type material.

1. Method for the production of directionally solidified Czochralski, float zone or multicrystalline silicon ingots or thin sheets or ribbon for making wafers for solar cells from silicon feedstock initially containing between 0.2 ppma and 10 ppma boron and between 0.1 ppma and 10 ppma phosphorous, characterized in that if the boron content in the silicon feedstock is higher than the phosphorous content, the boron content in the molten silicon is kept higher than the phosphorous content during the directional solidification process by adding boron discontinuously, continuously or substantially continuously to the molten silicon in order to extend the part of the directionally solidified ingot or the thin sheet or ribbon solidifying as p-type material, or if the content of phosphorous in the silicon feedstock is higher than the boron content, the phosphorous content in the molten silicon is kept higher than the boron content during the directional solidification process by adding phosphorous to the molten silicon discontinuously, continuously or substantially continuously in order to extend the part of the ingot or the thin sheet or ribbon solidifying as n-type material.
